(19) United States
(12) Patent Application Publication
(10) Pub. No.: US 2021/0147225 A1
(43) Pub. Date: May 20, 2021

(54) METHOD AND APPARATUS FOR MANUFACTURING PARTICLES

(71) Applicant: WEINBERG MEDICAL PHYSICS INC., North Bethesda, MD (US)

(72) Inventor: Irving N. Weinberg, Bethesda, MD (US)

(21) Appl. No.: 17/130,286

(22) Filed: Dec. 22, 2020

Related U.S. Application Data
(63) Continuation-in-part of application No. 15/427,372, filed on Feb. 8, 2017, now Pat. No. 10,900,135.
(60) Provisional application No. 62/292,966, filed on Feb. 9, 2016.

(51) Int. Cl. B82B 3/00; C25D 1/00

(52) U.S. Cl. CPC B82B 3/0033; C25D 1/006

(57) ABSTRACT

An apparatus and method are provided for manufacturing particles. The apparatus and method may be implemented in a roll-to-roll fashion for continuous or intermittent production of particles, using membranes passing from station to station propelled by rollers.

### PRIORITY

This application claims priority to U.S. patent application Ser. No. 15/427,372, filed Feb. 8, 2017, and entitled “METHOD AND APPARATUS FOR MANUFACTURING PARTICLES” and U.S. Provisional Patent Application 62/292,966, entitled “ROLL TO ROLL MANUFACTURE OF INORGANIC PARTICLES USING FLEXIBLE TEMPLATES AND ELECTROPLATING” filed Feb. 9, 2016, the disclosures of which are incorporated by reference in their entirety.

### FIELD

A method and apparatus for manufacturing particles. Said particles may be used for medical, veterinary, or industrial applications.

### BACKGROUND

Shape-defined particles have been fabricated with template-guided electroplating synthesis. This process starts with a membrane containing many holes of uniform size. The membrane is coated on one side with an electrically conductive material (for example by sputtering a metal) so that one side of the holes is covered with conductive material and the other side is not. The membrane is then immersed into a bath containing a solution of the material to be deposited. The membrane is connected to a voltage source and then acts as an electrode for electrochemical deposition within the holes. The membrane is dissolved and the deposited material is freed. The now-freed deposited material takes the shape of the holes. One deficiency of the prior art is that if the holes are too large, it is difficult or impossible to entirely cover one side of the holes with sputtered conductive material.

### SUMMARY

Disclosed embodiments use template-guided electroplating to manufacture particles.

Although particle manufacturing using electroplating techniques has been done using with a non-electrically conductive (abbreviated as “non-conductive” in this description) membrane with precut through-holes. In such processes, the non-conductive membrane must be capped on one side of the holes with a conductive material in order to proceed with an electroplating process. In the present disclosure, the non-conductive membrane is sealed against an electrically conductive membrane (abbreviated as “conductive membrane” in this description), and holes are created after such sealing.

### BRIEF DESCRIPTION OF THE FIGURES

FIG. 1 illustrates an apparatus that includes a conductive membrane or substrate, which may have a backing membrane for adding strength to membrane.

FIG. 2 illustrates an exemplary step in the process of creating particles with the apparatus of FIG. 1 in which the cutter has created exemplary holes in the membrane;

FIG. 3 illustrates a step of addition of a solution 300 containing a material to be deposited into holes created by the cutter of FIGS. 1-2;

FIG. 4 shows the step of electrically connecting attaching a current or voltage source to membrane, so that material from solution is deposited into holes of FIGS. 2-3;

FIG. 5 shows the results of an example of such repeated exposure to solutions and/or repeated cutting;

FIG. 6 shows particles and after removal from the membranes; and

FIG. 7 shows illustrates a flowchart of a method according to FIGS. 1-6.

### DETAILED DESCRIPTION

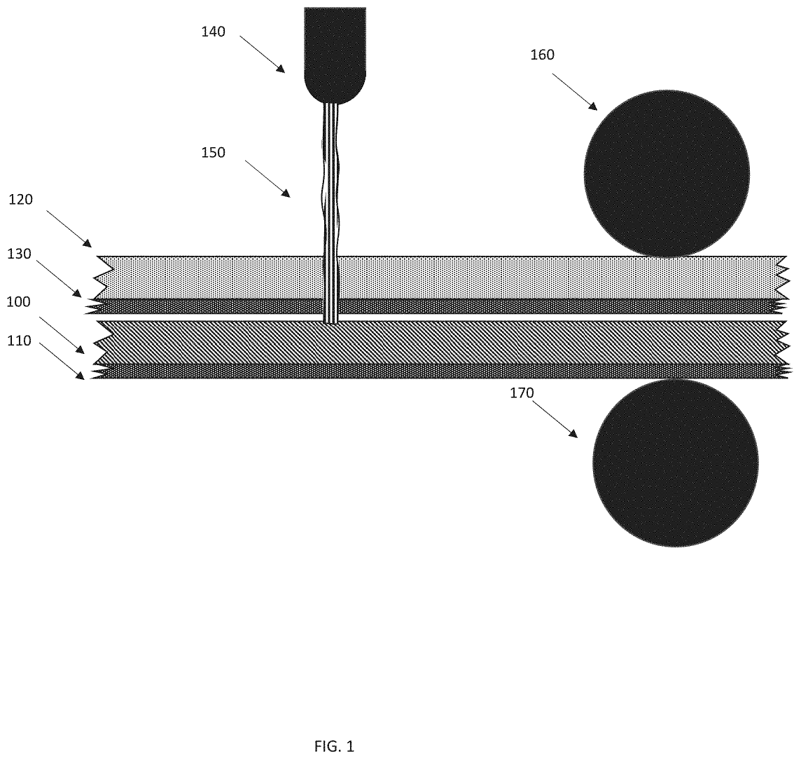

The present invention is a method and apparatus for production of particles in combination with electroplating. The invention may be implemented in a roll-to-roll fashion for continuous or intermittent production of particles, for example as in FIG. 1 using membranes 100 and 120 passing from station to station propelled by rollers 160 and 170. For the purposes of this specification, the term “particle” is used broadly, and can mean nanoscale particles, microscale particles, or large structures from millimeters to centimeters or more in size.

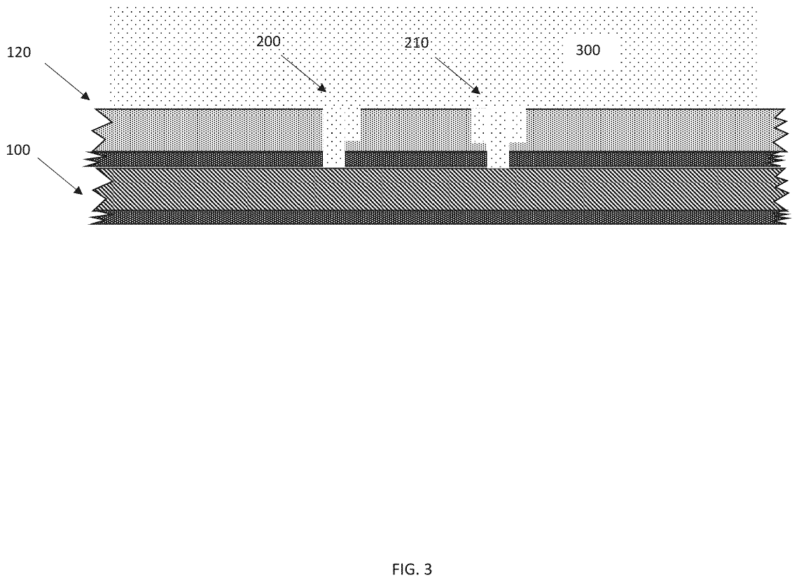

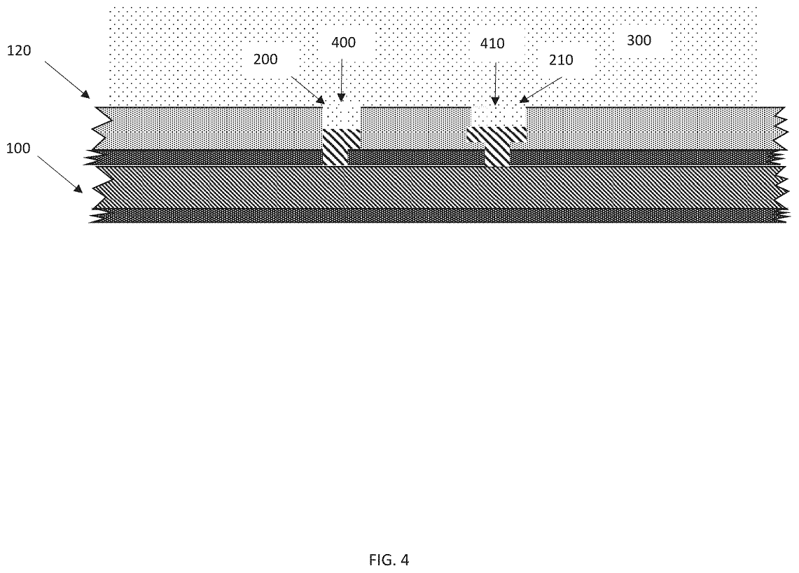

Prior methods employed non-conductive membranes with precut through-holes, said holes being capped on one side of the holes with a conductive material (for example through sputtering) before subsequent electroplating steps were applied. In the present disclosure, the non-conductive membrane (example shown as 120) is sealed against a conductive membrane (example shown as 100) and holes in the non-conductive membrane (examples shown as 200 and 210) are created after such placement. Said holes can be created by laser beams or other tools 140 and 150. Examples of subsequent electroplating of material into the holes are shown in FIGS. 3 to 7.

Advantages of the present disclosure over the prior art include: (1) the holes created with the shaping tools may be more complex than in the prior art (for example including non-through-hole segments); (2) sealing against a conducting layer permits the conductive capping of larger holes than would be possible with sputtering onto holes as in the prior art; and (3) the hole/deposition process may be applied in multiple steps to create complex particles.

The apparatus includes at least one conductive membrane or polymer layer 100 and at least one other non-conductive membrane or polymer layer 120. Non-conductive membrane 120 may have an adhesive membrane 130 that may assist in adhering membrane 120 to membrane 100. Membranes 100 and 130 may be attached to membranes 100 and 130 (respectively) in the course of operation of the apparatus. For the purposes of this description, the terms “membrane” and “layer” can include any material and multiple possible configurations of said material, but for clarity the membranes are represented in FIG. 1 in sheet form. Although illustrated as a one-dimensional layer in FIG. 1, it is understood that the membrane can be a sheet or ribbon or even a three-dimensional structure that is moved through space.

One or more of membranes 100, 110, 120, 130 may be reel stock, as described in U.S. patent application Ser. No. 15/427,372, filed Feb. 8, 2017, and entitled “Method and Apparatus for Manufacturing Particles”. For purposes of this description, “reel stock” is defined as a material that can be supplied on a reel. The present invention may be realized by starting with a non-conducting reel stock 110 and subsequently depositing conductive material (for example by sputtering copper or spraying conductive graphite powder onto membrane 110) to create the electrically conductive membrane 100.

Non-conductive layer 120 may be deposited directly on conductive layer 100, for example by spraying a thermoplastic or other non-conductive material. The distribution of such deposition need not be uniform. For example, one or more regions of conductive layer 100 may be left uncovered by the non-conductive later 120, so that subsequent electroplating or electroless deposition selectively occurs on the uncovered region of conductive layer 100.

In another embodiment, at least one section of non-conductive layer 120 may be deposited directly on conductive layer 100, for example by immersing the conductive layer 100 into, or by spraying onto the conductive layer 100, a polymer or other material that is selectively stabilized (for example by cross-linking or polymerization) upon exposure to light from tool 140 or other light source. The non-stabilized sections of the material may be washed off or otherwise dissolved or removed to create holes in which subsequent electroplating or electroless deposition occurs. In an embodiment, at least one section of non-conductive layer may be destabilized upon exposure to light, and then may be washed off or otherwise dissolved or removed to create holes in which subsequent electroplating or electroless deposition occurs. In an embodiment, a combination of the above methods may be employed, for example using different tools, laser wavelengths or intensities, and/or different washing or solvent solutions to make complex structures in one or more non-conductive or conductive layers.

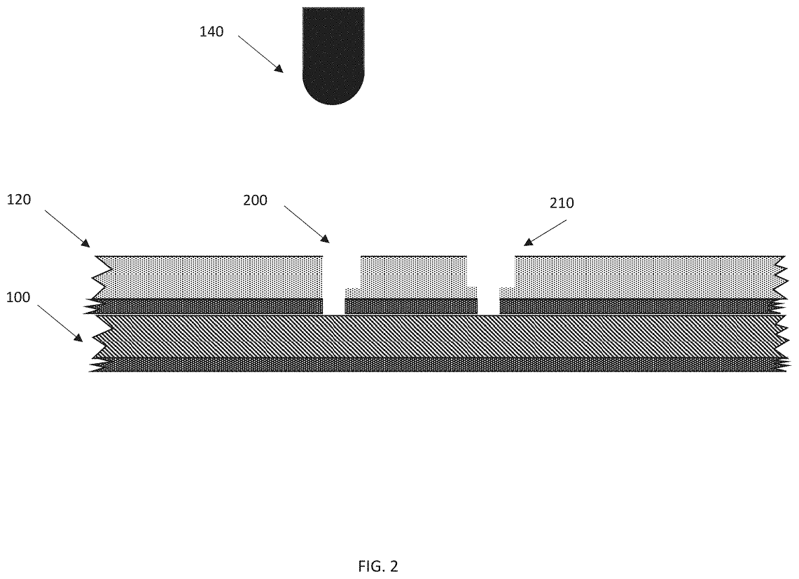

The steps shown in FIGS. 2-7 may be implemented as membranes 100 and/or 120 pass through various stations, in order to realize continuous production of particles.

As illustrated in FIG. 1, membranes 100 and 120 have been drawn close to one another to create a watertight seal between them. In an embodiment, this drawing close action may be implemented by the rollers 160 and 170 of FIG. 1, although other methods of creating the seal may be employed. A cutting or shaping tool, for example a visible-light laser or spatial-light modulating apparatus (or some other tool), is shown as 140 with beam 150 (that may be photons or may be ions or electrons). Optional rollers 160 and 170 (as examples of the general class of instruments than can propel or otherwise move membranes) move membranes 100 or 120. Beam 150 of Cutter 140 may be used to create exemplary holes 200 and 210 in membrane 120. Cutting tool may have been moved with respect to the membranes 100 and 120, or the membranes may be moved with respect to the shaping tool, in order to create said holes. As shown in FIG. 2, at least one part of holes 200 and 210 in membrane 120 must contact membrane 100, but not all of the hole must do so.

It is understood that the holes may have a more complex structure than shown in FIG. 2, and that there may be many such holes. It is understood that one or more steps (not shown) may have been implemented to process or clean the holes. Examples of such optional steps include such as immersion or exposure of some or all of the apparatus in acid or to ultrasonic washing or to deposition of a ligand. It is understood that the laser or other shaping tool may be used to create structures other than holes, for example by polymerizing portions of membrane 120 so that said portion is not removed in subsequent processing steps.

Although FIG. 2 shows a laser or cutting tool 140 creating holes in membrane 120, it is understood that laser 140 may affect membrane 120 to create non-hole structures, for example by polymerizing portions of membrane 120 so that those irradiated portions are not dissolved in subsequent processing steps. Such capability further increases the potential complexity of particles built with the apparatus and method.

According to FIG. 3, the apparatus may be exposed to a solution 300, said solution containing a material to be deposited into holes 200 and 210. For example, solution 300 may contain ferric chloride, and deposit iron. Solution 300 may be an electrolyte solution containing other metallic ions or conductive materials that may be applied through electroplating methods.

A current or voltage source may be electrically connected a current or voltage source to membrane 100, so that material 400 and 410 from solution 300 is deposited into holes 200 and 210. Additional steps may similarly be taken to add additional holes or structures to these existing deposited sections and/or deposit additional materials to these existing deposited sections, through repeated exposure to solutions and/or repeated cutting and/or polymerization.

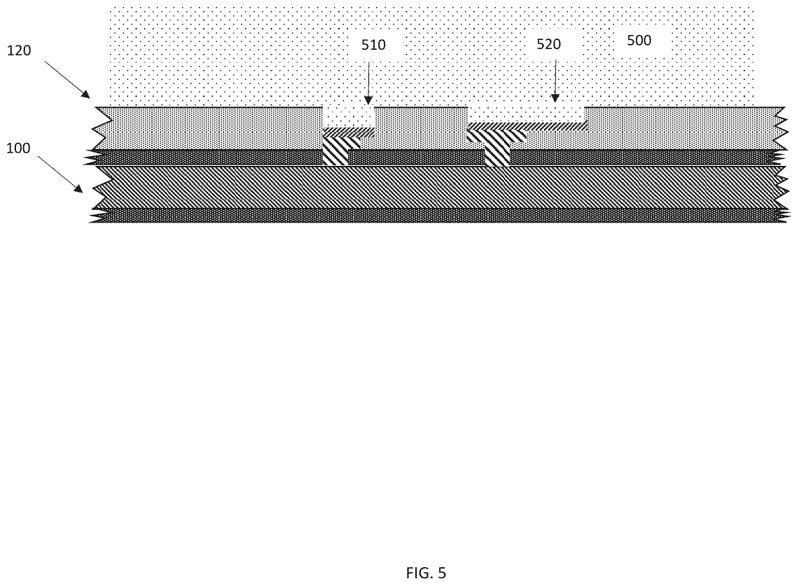

FIG. 5 shows the results of an example of such repeated exposure to solutions and/or repeated cutting. In this example, material 510 and 520 have been added from solution 500. Materials 510 and 520 may be subject to processing while still attached to one or more of the membranes, for example by heating.

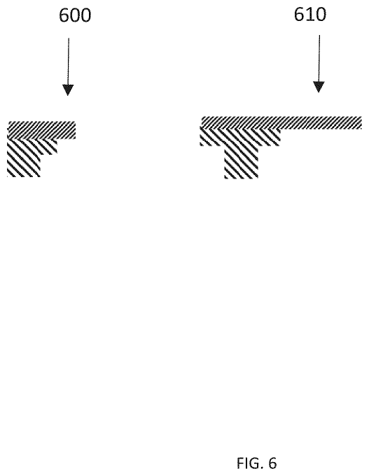

FIG. 6 shows particles 600 and 61o after removal from the membranes. The removal process (not shown) may have been accomplished by dissolving the membranes, or by mechanical or magnetic means. Particles 600 and 61o may be subject to further processing (not shown) for example annealing or washing or subsequent deposition of materials. Such subsequent deposition may be through electroless plating.

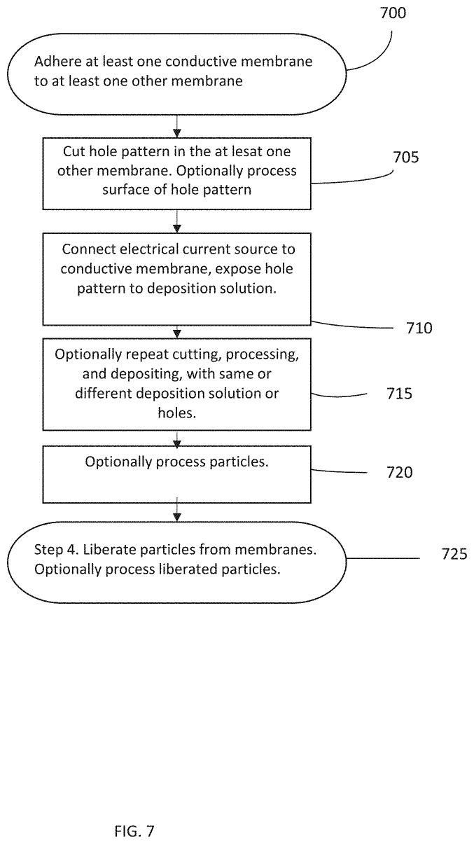

A method of the operation to manufacture the particles using the apparatus of FIGS. 1-6 is illustrated in FIG. 7 in which at least one conductive membrane is adhered to at least one other membrane 700. A hole pattern is cut in at least one other membrane and the surface of the hole is processed as necessary 705, for example as described with respect to FIG. 3. An electrical current source is connected to the conductive membrane and the cut hole pattern may be exposed to a deposition solution 710, for example by via immersion or spraying. Optionally, the processes of cutting a hole pattern and exposure of the hole pattern to a deposition may be repeated with the same or different deposition and at the same or different holes 715. Optionally, the particles may be processed, for example by heating as discussed above 720. Finally, the particles may be liberated from the membranes and optionally further processed 725.

It should be understood that the operations explained herein may be implemented in conjunction with, or under the control of, one or more general purpose computers running software algorithms to provide the presently disclosed functionality and turning those computers into specific purpose computers.

Moreover, those skilled in the art will recognize, upon consideration of the above teachings, that the above exemplary embodiments may be based upon use of one or more programmed processors programmed with a suitable computer program. However, the disclosed embodiments could be implemented using hardware component equivalents such as special purpose hardware and/or dedicated processors. Similarly, general purpose computers, microprocessor based computers, micro-controllers, optical computers, analog computers, dedicated processors, application specific circuits and/or dedicated hard wired logic may be used to construct alternative equivalent embodiments.

Moreover, it should be understood that control and cooperation of the above-described components may be provided using software instructions that may be stored in a tangible, non-transitory storage device such as a non-transitory computer readable storage device storing instructions which, when executed on one or more programmed processors, carry out he above-described method operations and resulting functionality. In this case, the term non-transitory is intended to preclude transmitted signals and propagating waves, but not storage devices that are erasable or dependent upon power sources to retain information.

Those skilled in the art will appreciate, upon consideration of the above teachings, that the program operations and processes and associated data used to implement certain of the embodiments described above can be implemented using disc storage as well as other forms of storage devices including, but not limited to non-transitory storage media (where non-transitory is intended only to preclude propagating signals and not signals which are transitory in that they are erased by removal of power or explicit acts of erasure) such as for example Read Only Memory (ROM) devices, Random Access Memory (RAM) devices, network memory devices, optical storage elements, magnetic storage elements, magneto-optical storage elements, flash memory, core memory and/or other equivalent volatile and non-volatile storage technologies without departing from certain embodiments. Such alternative storage devices should be considered equivalents.

While certain illustrative embodiments have been described, it is evident that many alternatives, modifications, permutations and variations will become apparent to those skilled in the art in light of the foregoing description. Accordingly, the various embodiments of, as set forth above, are intended to be illustrative, not limiting. Various changes may be made without departing from the spirit and scope of the invention.

1. An apparatus for manufacturing particles, the apparatus comprising:
one or more membrane layers that are conductive and one or more membrane layers that are non-conductive,
a tool to create holes or other structures in at least one of the non-conductive membrane layers so that one or more portions of one or more of the conductive membrane layers is exposed to an electrolyte or other solution through at least one portion of the created holes or other structures.

2. The apparatus of claim 1, where the one or more conductive and non-conductive membrane layers is a reel stock.

3. The apparatus of claim 1, where the shaping tool is a laser or other light source.

4. The apparatus of claim 1, wherein the one or more conductive and non-conductive membrane layers is a flexible reel stock, and further comprising at least one station in which material is deposited in a multiplicity of the holes in the roll of flexible reel stock, wherein a region of the reel stock is exposed to an electrolyte solution bath containing metallic ions.

5. The apparatus of claim 1, where the one or more of non-conductive layers have been created by selective stabilization of a material deposited on one or more of the conductive layers.

6. A method for manufacturing particles, wherein a tool is used to create said holes and other structures in at least one non-conductive membrane so that a portion of at least one other conductive membrane, is exposed through at least one portion of the created holes in the at least one non-conductive membrane, and wherein a region of the at least one non-conductive membrane is exposed to an electrolyte solution, so as to deposit material in a multiplicity of through-holes in the at least one non-conductive membrane.

7. The method of claim 6, where the tool is a laser.

8. The method of claim 6, wherein the at least one non-conductive membrane is a flexible reel stock.

9. The method of claim 6, where at least one section of the at least one non-conductive membrane has been created by selective stabilization of a non-conductive material deposited on one or more of the conductive layers through exposure to light, and holes in the non-conductive layer are created by removal of regions that have not been stabilized.
